(19) United States
(12) Patent Application Publication
(10) Pub. No.: US 2026/0020394 A1
(43) Pub. Date: Jan. 15, 2026

(54) BENDABLE DISPLAY MODULE AND AEROSOL GENERATION APPARATUS

(71) Applicant: YIBLA (USA) TECHNOLOGY CO., LTD, CITY OF INDUSTRY, CA (US)

(72) Inventor: Guangrui WANG, Puyang (CN)

(21) Appl. No.: 18/800,042

(22) Filed: Aug. 10, 2024

(30) Foreign Application Priority Data
Jul. 15, 2024 (CN) 202421673228.2

(51) Int. Cl. H01L 33/60; A24F 40/40; A24F 40/60; H01L 25/075

(52) U.S. Cl. CPC H10H 20/856; A24F 40/40; A24F 40/60; H01L 25/0753

(57) ABSTRACT

The present application are a bendable display module and an aerosol generation apparatus. The bendable display module includes a flexible display layer, a flexible printed circuit board with a circuit trajectory, and a plurality of light-emitting elements, where the flexible printed circuit board has a first surface in a thickness direction thereof; the plurality of light-emitting elements are distributed on the first surface of the flexible printed circuit board at intervals and are electrically connected to the circuit trajectory; and the flexible display layer is fixedly stacked on the first surface of the flexible printed circuit board and covers the light-emitting elements. By means of the bendable display module disclosed in the present application, the display area of the aerosol generation apparatus can be increased, so that the aerosol generation apparatus can display more visual information to a user.

### CROSS REFERENCE TO RELATED APPLICATIONS

The present application claims the priority of Chinese patent application No. 202421673228.2, filed on Jul. 15, 2024, and contents of which are incorporated herein by reference.

### TECHNICAL FIELD

The present application relates to the technical field of electronic atomization, in particular to a bendable display module and an aerosol generation apparatus.

### BACKGROUND

An aerosol generation apparatus is an electronic device that can atomize aerosol forming substances such as tobacco tar and medical solutions stored therein into aerosols in an electric heating manner. The existing aerosol generation apparatus on the market usually includes structures such as an atomization core, a power supply module and an accommodating compartment, where the accommodating compartment generally accommodates the aerosol forming substances, and the aerosol forming substances in the accommodating compartment can be conducted to the atomization core under the capillary action; in a process that a user uses the aerosol generation apparatus for suction, the power supply module supplies electric energy to the atomization core, so that the atomization core can be electrified for heating; and heat generated by electrifying and heating of the atomization core can be used for atomizing the aerosol forming substances conducted to the atomization core into the aerosols that can be inhaled by the user.

With the continuous use of the aerosol generation apparatus, the power supply charge level of the aerosol generation apparatus and the amount of the aerosol forming substances will be gradually reduced, and in order to facilitate the user to know the residual charge level of the aerosol generation apparatus and the residual amount of the aerosol forming substances directly at any time, the aerosol generation apparatus is usually externally equipped with a display screen that can display information such as the residual charge level and the residual amount of the aerosol forming substances. However, the existing aerosol generation apparatus with the display screen generally has the following problem:

the display screen used is usually a display screen with a rigid glass substrate, so that the display screen can usually only be mounted on one outer surface of the aerosol generation apparatus (such as a front surface, a back surface or a side surface of the aerosol generation apparatus); in addition, in order to facilitate the user to carry and use the aerosol generation apparatus, the size of the aerosol generation apparatus is generally small, resulting in the problem of small display area of the aerosol generation apparatus; however, with the continuous development of an electronic atomization technology, the information that needs to be displayed on the display screen increases, so that how to increase the display area of the aerosol generation apparatus to enable the aerosol generation apparatus to display more information is an urgent technical problem to be solved by those skilled in the art.

### SUMMARY

The present application mainly aims to provide a bendable display module and an aerosol generation apparatus, and aims to solve the technical problem of small display area of an existing aerosol generation apparatus with a display screen.

In order to achieve the above purpose, in a first aspect, the present application provides a bendable display module. The bendable display module comprises:
a flexible printed circuit board with a circuit trajectory, where the flexible printed circuit board has a first surface in a thickness direction thereof;
a plurality of light-emitting elements which are distributed on the first surface at intervals and are electrically connected to the circuit trajectory; and
a flexible display layer which is fixedly stacked on the first surface and covers the light-emitting elements, where the flexible display layer has a plurality of light-transmitting regions, each of the light-transmitting regions is provided opposite to at least one of the light-emitting elements, and a region of the flexible display layer apart from the light-transmitting regions is a light-shielding region.

In some embodiments, the bendable display module further comprises a current driving element and a current input interface, where the first surface has a first mounting region and a second mounting region which are connected to each other, the area of the first mounting region is greater than that of the second mounting region, the second mounting region is provided on an edge of the flexible printed circuit board, the plurality of light-emitting elements are fixed to the first mounting region, and the current driving element and the current input interface are mounted on the second mounting region at intervals and are electrically connected to the circuit trajectory.

In some embodiments, a notch is formed in the edge of the flexible printed circuit board, the second mounting region is located inside the notch, and a region of the first surface apart from the second mounting region is the first mounting region.

In some embodiments, a plurality of test points made of metal materials are further provided on the second mounting region in an exposed manner, and the plurality of test points are electrically connected to the circuit trajectory.

In some embodiments, the bendable display module further comprises a metal sheet, where the metal sheet is fixed to one side of the flexible printed circuit board facing away from the second mounting region.

In some embodiments, the bendable display module further comprises a flexible flat cable, where one end of the flexible flat cable is inserted into the current input interface.

In some embodiments, the bendable display module further comprises a first viscous layer, where the flexible printed circuit board further has a second surface facing away from the first surface, and the first viscous layer is provided on the second surface.

In some embodiments, the bendable display module further comprises a flexible light-reflecting layer, where the flexible light-reflecting layer covers the first surface, and the light-emitting elements are exposed out of the flexible light-reflecting layer.

In some embodiments, the bendable display module further comprises a flexible diffusion layer, where the flexible diffusion layer is attached to a surface of one side of the flexible display layer facing the flexible printed circuit board, and the flexible diffusion layer covers the light-transmitting regions.

In some embodiments, the bendable display module further comprises a flexible light-shielding layer, where a plurality of light-transmitting holes are formed in the flexible light-shielding layer, the flexible light-shielding layer is sandwiched between the flexible printed circuit board and the flexible display layer, and each of the light-transmitting holes is provided opposite to at least one of the light-transmitting regions.

In some embodiments, the flexible light-shielding layer is made of an opaque silica gel, rubber or silicone rubber material.

In some embodiments, a second viscous layer is provided on a surface of one side of the flexible light-shielding layer facing the flexible printed circuit board.

In some embodiments, a third viscous layer is provided on a surface of one side of the flexible display layer facing the flexible printed circuit board.

In some embodiments, the light-emitting elements are LED lamp beads. In some embodiments, the light-emitting elements are LED lamp beads with dimensions being 0.5-1.5 mm in length, 0.2-0.8 mm in width and 0.1-0.8 mm in thickness.

In some embodiments, the light-emitting elements are LED lamp beads with dimensions being 1.0 mm in length, 0.5 mm in width and 0.4 mm in thickness.

In some embodiments, the flexible printed circuit board comprises any one of a polyimide film and a polyester film.

In order to achieve the above purpose, in a second aspect, the present application further provides an aerosol generation apparatus. The aerosol generation apparatus comprises an outer shell, a power supply module mounted inside the outer shell, and the bendable display module according to any one of the above embodiments, where the bendable display module is fixed to an outer surface of the outer shell and surrounds the outer shell in a circumferential direction of the outer shell; and the flexible printed circuit board is located between the flexible display layer and the outer shell and is electrically connected to the power supply module.

Compared with the prior art, the present application has the beneficial effects as follows:
in the technical solutions of the present application, the plurality of light-emitting elements are distributed on the first surface of the flexible printed circuit board, and the flexible display layer having the plurality of light-transmitting regions is fixed to the first surface of the flexible printed circuit board and covers the light-emitting elements, so that the plurality of light-emitting elements can be packaged between the flexible display layer and the flexible printed circuit board; the flexible printed circuit board can serve as a mounting carrier for the plurality of light-emitting elements, the circuit trajectory on the flexible printed circuit board can serve as a medium for electrically connecting the plurality of light-emitting elements to an external power supply, and after the plurality of light-emitting elements are connected to the external power supply by means of the circuit trajectory of the flexible printed circuit board, the plurality of light-emitting elements are electrified to emit light, and the emitted light can be displayed in the light-transmitting regions of the flexible display layer, that is, the light-transmitting regions of the flexible display layer can serve as light display regions of the display module, thereby achieving a display function of the display module. The flexible display layer and the flexible printed circuit board are of flexible structures, so that the display module formed by stacking the flexible display layer and the flexible printed circuit board is also of a flexible structure and can be bent. Thus, when the bendable display module provided in the present application is applied to the aerosol generation apparatus, on the basis of the bendable characteristic of the display module, the display module can cover a plurality of outer surfaces of the aerosol generation apparatus at the same time in a winding manner, making the light display regions of the display module be distributed on the plurality of outer surfaces of the aerosol generation apparatus, thereby increasing the display area of the aerosol generation apparatus, and enabling the aerosol generation apparatus to display more information to a user.

### BRIEF DESCRIPTION OF THE DRAWINGS

In order to explain embodiments of the present application or technical solutions in the prior art more clearly, drawings needed in descriptions of the embodiments or the prior art will be briefly introduced below. Obviously, the drawings in the following descriptions are only some embodiments of the present application, and for a person of ordinary skill in the art, other drawings can be obtained according to structures shown in these drawings without involving any inventive effort.

FIG. 1 is a three-dimensional structural schematic diagram of a bendable display module in an embodiment of the present application;

FIG. 2 is a planar schematic diagram of FIG. 1 after expansion;

FIG. 3 is a sectional view of FIG. 2 in an A-A direction;

FIG. 4 is a partial sectional view of a bendable display module in an embodiment of the present application;

FIG. 5 is a front schematic diagram of a flexible printed circuit board in an embodiment of the present application;

FIG. 6 is a back schematic diagram of a flexible printed circuit board in an embodiment of the present application;

FIG. 7 is a front schematic diagram of a flexible printed circuit board in another embodiment of the present application;

FIG. 8 is a planar schematic diagram of a flexible display layer in an embodiment of the present application;

FIG. 9 is a planar schematic diagram of a flexible display layer and a flexible diffusion layer after combination in an embodiment of the present application;

FIG. 10 is a planar schematic diagram of a flexible light-shielding layer in an embodiment of the present application; and

FIG. 11 is a structural schematic diagram of an aerosol generation apparatus in an embodiment of the present application.

### DESCRIPTION OF REFERENCE NUMERALS

1—flexible printed circuit board, 11—first surface, 111—first mounting region, 112—second mounting region, 12—second surface, 13—notch, 14—circuit trajectory, and 15—first viscous layer;
2—light-emitting element;
3—flexible display layer, 31—light-transmitting region; 32—light-shielding region, and 33—third viscous layer;
41—current driving element, 42—current input interface, and 43—test point;
51—metal sheet, 511—positioning hole, and 52—flexible flat cable;
6—flexible light-reflecting layer;
7—flexible diffusion layer, and 71—fourth viscous layer;
8—flexible light-shielding layer, 81—light-transmitting hole, and 82—second viscous layer; and
9—outer shell.

### DETAILED DESCRIPTION OF EMBODIMENTS

The technical solutions in embodiments of the present application will be described clearly and completely below in conjunction with the accompanying drawings in the embodiments of the present application. Obviously, the described embodiments are only a part of embodiments of the present application, not all of them. On the basis of the embodiments of the present application, all other embodiments obtained by those of ordinary skill in the art without involving any inventive effort should fall within the scope of protection of the present application.

It should be noted that if the embodiments of the present application involve directional indications (such as up, down, left, right, front, back, etc.), the directional indications are only used to explain the relative position relationship and motions of components in a specific attitude, and if the specific attitude is changed, the directional indications will be changed accordingly.

In addition, if the embodiments of the present application include descriptions involving “first”, “second” and the like, the descriptions involving “first”, “second” and the like are only for description purposes, and cannot be understood as indicating or implying the relative importance or implicitly indicating the number of indicated technical features. Thus, the features defined as “first” and “second” can explicitly or implicitly include at least one such feature. In addition, if “and/or” appears in the full text, its meanings include three parallel solutions, for example, “A and/or B” includes solution A, or solution B, or a solution satisfying A and B at the same time. Besides, the technical solutions of the embodiments can be combined with one another on the basis that such combinations can be implemented by a person of ordinary skill in the art, and when the combinations of the technical solutions are contradictory or cannot be implemented, it should be considered that such combinations of the technical solutions do not exist and do not fall within the scope of protection claimed by the present application.

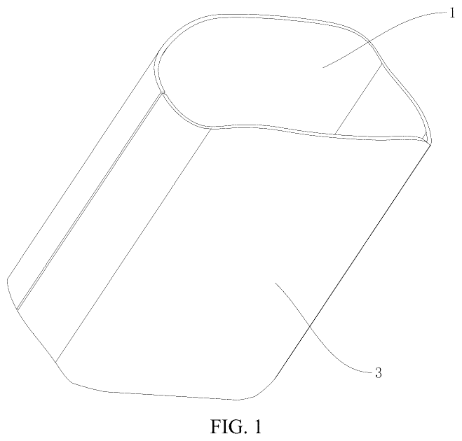

Reference is made to FIGS. 1-3 and FIGS. 5-6. An embodiment of the present application provides a bendable display module. The bendable display module includes a flexible printed circuit board 1, a flexible display layer 3, and a plurality of light-emitting elements 2, where the flexible printed circuit board 1 has a circuit trajectory 14, and the flexible printed circuit board 1 has a first surface 11 in a thickness direction thereof; the plurality of light-emitting elements 2 are distributed on the first surface 11 of the flexible printed circuit board 1 at intervals and are electrically connected to the circuit trajectory 14; and the flexible display layer 3 is fixedly stacked on the first surface 11 of the flexible printed circuit board 1 and covers the light-emitting elements 2, the flexible display layer 3 has a plurality of light-transmitting regions 31, each of the light-transmitting regions 31 is provided opposite to at least one of the light-emitting elements 2, and a region of the flexible display layer 3 apart from the light-transmitting regions 31 is a light-shielding region 32.

In this embodiment, those skilled in the art can understand that the flexible printed circuit board 1 is also called an FPC (flexible printed circuit) board, is a flexible circuit board printed with the circuit trajectory 14, and has the advantages of good flexibility, light weight and small thickness, in a specific manufacturing technology, the needed flexible printed circuit board 1 can be obtained by printing the circuit trajectory 14 on a flexible film, and the flexible film can be a polymer material having the high performance (such as the excellent heat resistance, chemical stability and bendability), for example, a polyimide film and a polyester film.

In this embodiment, during specific implementation, the light-emitting elements 2 can be components that can be electrified to emit light, such as LED lamp beads. In some optional implementation manners, the light-emitting elements 2 can be LED lamp beads with dimensions being 0.5-1.5 mm in length, 0.2-0.8 mm in width and 0.1-0.8 mm in thickness. Preferably, the light-emitting elements 2 can specifically be LED lamp beads in the model of 0402, and the LED lamp beads in such model have the dimensions being 1.0 mm in length, 0.5 mm in width and 0.4 mm in thickness; and through repeated tests, when the display module provided in this embodiment uses the LED lamp beads in such model as the light-emitting elements 2, compared with LED lamp beads in other dimensions, the display module can obtain the better display effect and the high quality reliability. The light-emitting elements 2 can be fixed to the first surface 11 of the flexible printed circuit board 1 through welding and bonding (for example, bonding by means of insulating glue or conductive glue), and be electrically connected to the circuit trajectory 14 of the flexible printed circuit board 1.

In this embodiment, during specific implementation, the flexible display layer 3 can be made of flexible materials such as polyimide (PI), polyethylene glycol terephthalate (PET), polyethylene naphthalate (PEN), liquid crystal polymers (LCP), polyvinyl alcohol (PVA) and polydimethylsiloxane (PDMS), all that is required is to meet use requirements, and the specific material of the flexible display layer 3 is not specifically limited in this embodiment. When the flexible display layer 3 is made of the transparent flexible material, the light-transmitting regions 31 and the light-shielding region 32 can be formed on the flexible display layer 3 through coating of light-shielding ink, for example, when the flexible display layer 3 is the transparent polyimide film, a surface of the polyimide film can be coated with the light-shielding ink in a preset manner, a region coated with the light-shielding ink in the polyimide film can be regarded as the light-shielding region 32 of the flexible display layer 3, and regions that are not coated with the light-shielding ink in the polyimide film can be regarded as the light-transmitting regions 31 of the flexible display layer 3. Moreover, when the flexible display layer 3 is made of the opaque flexible material, the light-transmitting regions 31 and the light-shielding region 32 can be formed on the flexible display layer 3 through laser engraving, for example, when the flexible display layer 3 is the opaque PET film, the needed light-transmitting regions 31 can be engraved on a surface of the PET film through laser engraving (the light-transmitting regions 31 at this time are essentially through holes), and a region that is not engraved in the PET film forms the light-shielding region 32. It should be noted here that during specific implementation, the shapes, sizes and position distribution of the light-transmitting regions 31 can be determined according to the actual use requirements, and are not specifically limited in this embodiment. Optionally, the light-transmitting regions 31 can be in shapes of characters, numbers, letters, dots and lines, and when the light emitted by the light-emitting elements 2 reaches the light-transmitting regions 31, light display information in the corresponding shapes can be displayed, for example, when the light emitted by the light-emitting elements 2 reaches the light-transmitting regions 31 in the shapes of letters, a user can observe light-emitting letters on the flexible display layer 3, so that the light display information in multiple different shapes can be obtained by combining the plurality of light-transmitting regions 31 in different shapes. Thus, when the bendable display module provided in this embodiment is applied to an aerosol generation apparatus, various information (such as the residual charge level, the operating power, the residual amount of aerosol forming substances and preset patterns) of the aerosol generation apparatus can be represented by the light display information in the different shapes. In addition, the number of the light-emitting elements 2 corresponding to each light-transmitting region 31 can also be determined according to the actual use requirements, and is also not specifically limited in this embodiment.

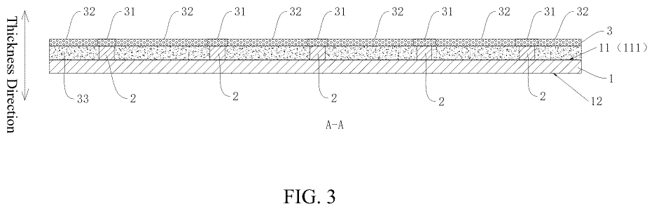

In this embodiment, it should also be noted that during specific implementation, the flexible display layer 3 can be fixedly stacked on the first surface 11 of the flexible printed circuit board 1 through bonding. Optionally, as shown in FIG. 3, a third viscous layer 33 is provided on a surface of one side of the flexible display layer 3 facing the flexible printed circuit board 1, the flexible display layer 3 can be conveniently and reliably bonded to the flexible printed circuit board 1 by means of the third viscous layer 33 to form an integrated laminated structure. During specific implementation, the third viscous layer 33 can be a double-faced adhesive tape, a structural adhesive, an optical transparent adhesive and a pressure-sensitive adhesive, all that is required is to meet the use requirements, and it is not specifically limited in this embodiment.

In the technical solutions provided by the embodiments of the present application, the plurality of light-emitting elements 2 are distributed on the first surface 11 of the flexible printed circuit board 1, and the flexible display layer 3 having the plurality of light-transmitting regions 31 is fixed to the first surface 11 of the flexible printed circuit board 1 and covers the light-emitting elements 2, so that the plurality of light-emitting elements 2 can be packaged between the flexible display layer 3 and the flexible printed circuit board 1; the flexible printed circuit board 1 can serve as a mounting carrier for the plurality of light-emitting elements 2, the circuit trajectory 14 on the flexible printed circuit board 1 can serve as a medium for electrically connecting the plurality of light-emitting elements 2 to an external power supply, and after the plurality of light-emitting elements 2 are connected to the external power supply (the external power supply can be a power supply module of the aerosol generation apparatus) by means of the circuit trajectory 14 of the flexible printed circuit board 1, the plurality of light-emitting elements 2 are electrified to emit light, and the emitted light can be displayed in the light-transmitting regions 31 of the flexible display layer 3, that is, the light-transmitting regions 31 of the flexible display layer 3 can serve as light display regions of the display module, thereby achieving a display function of the display module. The flexible display layer 3 and the flexible printed circuit board 1 are of flexible structures, so that the display module formed by stacking the flexible display layer 3 and the flexible printed circuit board 1 is also of a flexible structure and can be bent. Thus, when the bendable display module provided in the present application is applied to the aerosol generation apparatus, on the basis of the bendable characteristic of the display module, the display module can cover a plurality of outer surfaces of the aerosol generation apparatus at the same time in a winding manner, making the light display regions of the display module be distributed on the plurality of outer surfaces of the aerosol generation apparatus, thereby increasing the display area of the aerosol generation apparatus, and enabling the aerosol generation apparatus to display more information to a user.

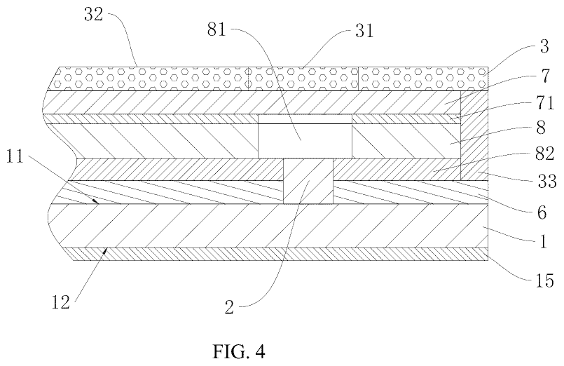

Reference is made to FIG. 4. In some optional embodiments of the present application, the bendable display module further includes a first viscous layer 15, where the flexible printed circuit board 1 further has a second surface 12 facing away from the first surface 11, and the first viscous layer 15 is provided on the second surface 12. Thus, in some use scenes in which the bendable display module in this embodiment is applied to the aerosol generation apparatus, the entire display module can be quickly attached to the outer surface of the aerosol generation apparatus by means of the first viscous layer 15, thereby improving the mounting convenience of the display module. During specific implementation, the first viscous layer 15 can be glue in the type such as a double-faced adhesive tape and a structural adhesive, all that is required is to meet the use requirements, and it is not specifically limited in this embodiment.

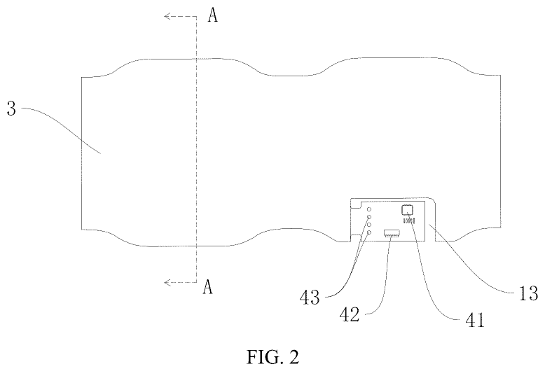

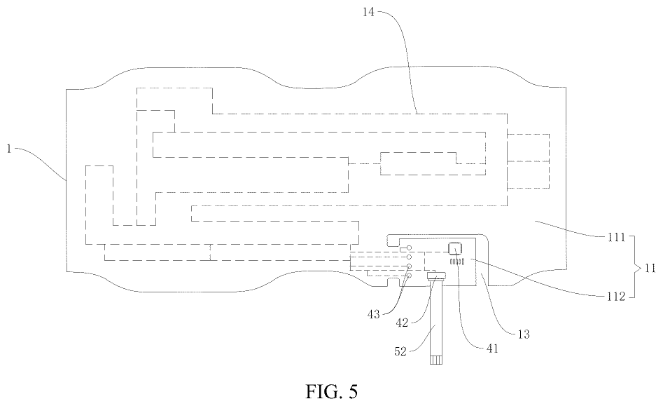

Reference is made to FIG. 2 and FIG. 5. In some optional embodiments of the present application, the bendable display module further includes a current driving element 41 and a current input interface 42, where the first surface 11 has a first mounting region 111 and a second mounting region 112 which are connected to each other, the area of the first mounting region 111 is greater than that of the second mounting region 112, the second mounting region 112 is provided on an edge of the flexible printed circuit board 1 (for example, assuming that the flexible printed circuit board 1 is a strip-shaped sheet having a certain length and width, the second mounting region 112 can be provided on a length edge or a width edge of the flexible printed circuit board 1), the plurality of light-emitting elements 2 are fixed to the first mounting region 111, and the current driving element 41 and the current input interface 42 are mounted on the second mounting region 112 at intervals and are electrically connected to the circuit trajectory 14.

In this embodiment, by providing the current input interface 42 electrically connected to the circuit trajectory 14, in some use scenes in which the bendable display module in this embodiment is applied to the aerosol generation apparatus, the light-emitting elements 2 of the display module can be conveniently electrically connected to the power supply module of the aerosol generation apparatus, for example, during specific application, all that is required is to connect one end of one wire to the current input interface 42 and connect the other end of the wire to the power supply module of the aerosol generation apparatus, the electrical connection between the light-emitting elements 2 and the power supply module of the aerosol generation apparatus can be quickly achieved, and the operation is very convenient. The current input interface 42 can be in the structural form of a universal connector and can also be communication interfaces in other types, all that is required is to meet the use requirements, and it is not specifically limited in this embodiment.

In this embodiment, by providing the driving element electrically connected to the circuit trajectory 14, in some use scenes in which the bendable display module in this embodiment is applied to the aerosol generation apparatus, after the power supply module of the aerosol generation apparatus is connected by means of the current input interface 42, the light-emitting elements 2 can be conveniently driven by the power supply module to emit light in the preset manner so as to display needed information on the flexible display layer 3. It should be noted here that during specific implementation, the driving element can be a universal driving chip in the art, and the specific structure and use principle thereof are well-known to those skilled in the art and are therefore not repeated here.

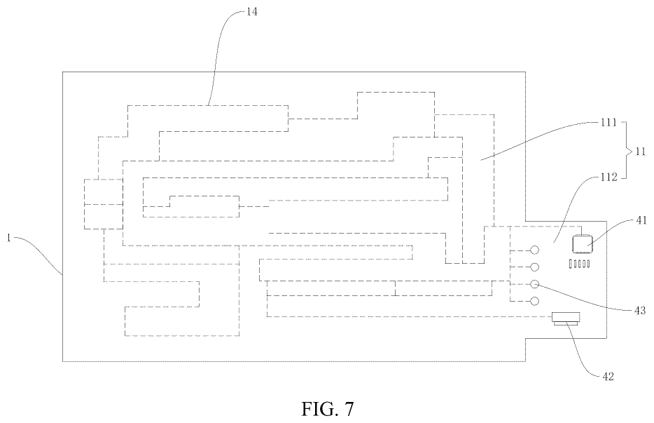

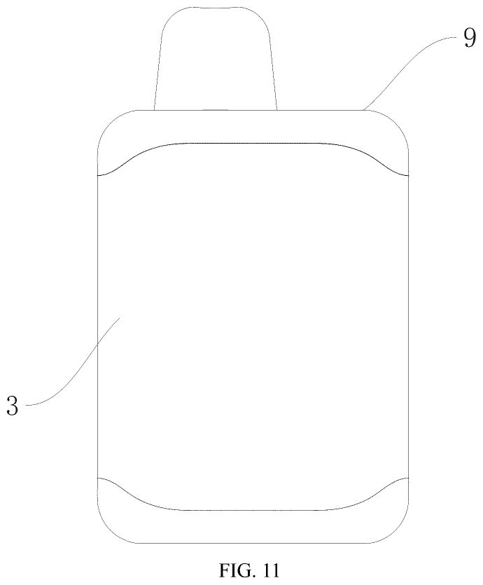

Reference is made to FIGS. 1-2, FIGS. 5-6 and FIG. 11. In some optional embodiments of the present application, a notch 13 is formed in the edge of the flexible printed circuit board 1, the second mounting region 112 is located inside the notch 13, and a region of the first surface 11 of the flexible printed circuit board 1 apart from the second mounting region 112 is the first mounting region 111. Through such arrangement, compared with the arrangement manner of providing the second mounting region 112 of the flexible printed circuit board 1 on the edge of the flexible printed circuit board 1 in a protruding manner (as shown in FIG. 7), in some use scenes in which the bendable display module in this embodiment is applied to the aerosol generation apparatus, in a process of mounting the display module on the outer surface of the aerosol generation apparatus in a surrounding manner in a circumferential direction of the aerosol generation apparatus, the risk of interference of the first mounting region 111 with the second mounting region 112 can be reduced, so that the display area of the display module in the circumferential direction of the aerosol generation apparatus can be conveniently increased. For example, assuming that the display module is a flexible strip-shaped sheet having a certain length and width, if the second mounting region 112 of the flexible printed circuit board 1 is provided on one width edge of the flexible printed circuit board 1 in the protruding manner (as shown in FIG. 7), in a process of mounting the strip-shaped display module on the outer surface of the aerosol generation apparatus in the surrounding manner in the circumferential direction of the aerosol generation apparatus, the second mounting region 112 of the flexible printed circuit board 1 easily overlaps with the other width edge of the flexible printed circuit board 1 to interfere with one end of the first mounting region 111 away from the second mounting region 112, so that it is difficult for the display module to enclose a complete closed-loop structure, and the display area of the aerosol generation apparatus in the circumferential direction thereof cannot be increased to the maximum extent. Moreover, in the technical solution provided in this embodiment, an avoidance design is performed on the second mounting region 112 of the flexible printed circuit board 1, that is, the second mounting region 112 of the flexible printed circuit board 1 is located inside the notch 13 formed in the edge of the flexible printed circuit board 1, thus in the process of mounting the display module on the outer surface of the aerosol generation apparatus in the surrounding manner in the circumferential direction of the aerosol generation apparatus, the situation that the end of the first mounting region 111 away from the second mounting region 112 interferes with the second mounting region 112 is effectively avoided, the display module can conveniently enclose the complete closed-loop structure, and the display area of the aerosol generation apparatus in the circumferential direction thereof can be increased to the maximum extent.

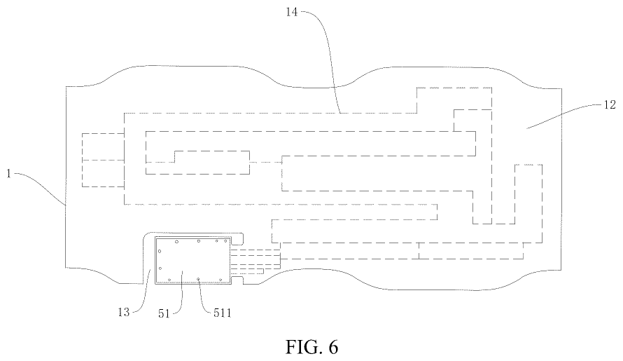

In this embodiment, it should be noted that in some specific application scenes, when the flexible printed circuit board 1 is a strip-shaped sheet having a certain length and width, the notch 13 for accommodating the second mounting region 112 can be formed in a length edge of the flexible printed circuit board 1 (as shown in FIGS. 5-6), and the notch 13 for accommodating the second mounting region 112 can also be formed in a width edge of the flexible printed circuit board 1, which is not specifically limited in this embodiment.

Reference is made to FIG. 5. In some optional embodiments of the present application, a plurality of test points 43 made of metal materials are further provided on the second mounting region 112 of the flexible printed circuit board 1 in an exposed manner, and the plurality of test points 43 are electrically connected to the circuit trajectory 14 of the flexible printed circuit board 1. Thus, by providing the plurality of test points 43 made of the metal materials, a tester can conveniently perform corresponding function tests or fault tests on the display module.

Reference is continuously made to FIG. 5. In some optional embodiments of the present application, the bendable display module further includes a flexible flat cable 52, where one end of the flexible flat cable 52 is inserted into the current input interface 42. Through such arrangement, in some use scenes in which the bendable display module in this embodiment is applied to the aerosol generation apparatus, a mounting person can conveniently and quickly electrically connect the display module to the power supply module of the aerosol generation apparatus, during specific operation, all that is required is to insert one end of the flexible flat cable 52 away from the current input interface 42 to a communication interface of the power supply module, and the operation is very convenient.

Reference is made to FIGS. 5-6. In some optional embodiments of the present application, the bendable display module further includes a metal sheet 51, where the metal sheet 51 can be fixed to one side of the flexible film facing away from the second mounting region 112 by means of glue. In this embodiment, the metal sheet 51 can reinforce (that is, enhance the strength) a portion of the flexible printed circuit board 1 including the second mounting region 112, so that in some use scenes in which the bendable display module in this embodiment is mounted on the outer surface of the aerosol generation apparatus, the portion of the flexible printed circuit board 1 where the driving element and the current input interface 42 are mounted can be conveniently positioned. In order to more conveniently position the portion of the flexible printed circuit board 1 where the driving element and the current input interface 42 are mounted, at least one positioning hole 511 is further formed in a surface of the metal sheet 51.

Reference is made to FIG. 4. In some optional embodiments of the present application, the bendable display module further includes a flexible light-reflecting layer 6, where the flexible light-reflecting layer 6 covers the first surface 11 of the flexible printed circuit board 1, and the light-emitting elements 2 are exposed out of the flexible light-reflecting layer 6. In this embodiment, the arrangement of the flexible light-reflecting layer 6 can improve the light display effect of the display module while ensuring that the display module can be bent. Specifically, after the light emitted by the light-emitting elements 2 irradiates the light-transmitting regions 31 of the flexible display layer 3, a part of the light will be reflected, and due to the existence of the flexible light-reflecting layer 6, the part of reflected light can be reflected back to the light-transmitting regions 31 of the flexible display layer 3 again to a certain extent, thereby increasing the light utilization rate, and enabling the display module to have the better light display effect. During specific implementation, the flexible light-reflecting layer 6 can be a flexible light-reflecting film (such as the transparent polyimide film), can also be a paint layer (optionally, in order to achieve the better light-reflecting effect, the white paint layer can be used as the flexible light-reflecting layer 6), and can also be a light-reflecting ink layer, all that is required is to meet the use requirements, and it is not specifically limited in this embodiment.

Reference is continuously made to FIG. 4. In some optional embodiments of the present application, the bendable display module further includes a flexible diffusion layer 7, where the flexible diffusion layer 7 can be attached to a surface of one side of the flexible display layer 3 facing the flexible printed circuit board 1 by means of glue, and the flexible diffusion layer 7 covers the light-transmitting regions 31. In this embodiment, the flexible diffusion layer 7 is provided between the plurality of light-emitting elements 2 and the plurality of light-transmitting regions 31, and the flexible diffusion layer 7 can uniformly diffuse the light emitted by the light-emitting elements 2, so that the light emitted by the light-emitting elements 2 can be more uniformly diffused to the light-transmitting regions 31 of the flexible display layer 3, thereby improving the light display uniformity of the display module. During specific implementation, the flexible diffusion layer 7 can be a transparent flexible film coated with fluorescent ink and can also be flexible diffusion films in other types, all that is required is to meet the use requirements, and it is not specifically limited in this embodiment. Optionally, in some implementation manners, the flexible diffusion layer 7 is a yellow fluorescent ink film, and the light emitted by the light-emitting elements 2 is blue light. Optionally, in some implementation manners, a fourth viscous layer 71 is provided on a surface of one side of the flexible diffusion layer 7 facing away from the flexible display layer 3, so that the flexible diffusion layer 7 and the flexible printed circuit board 1 (or the flexible light-reflecting layer 6, or an aftermentioned flexible light-shielding layer 8) can be bonded together; and the fourth viscous layer 71 can be a glue layer in the type such as a double-faced adhesive tape and a structural adhesive.

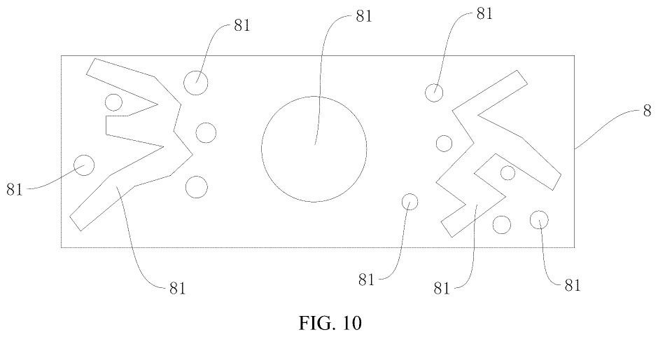

Reference is continuously made to FIG. 4 and FIG. 10. In some optional embodiments of the present application, the bendable display module further includes the flexible light-shielding layer 8, where a plurality of light-transmitting holes 81 are formed in the flexible light-shielding layer 8, the flexible light-shielding layer 8 is sandwiched between the flexible printed circuit board 1 and the flexible display layer 3, and each of the light-transmitting holes 81 is provided opposite to at least one of the light-transmitting regions 31. In this embodiment, the loss of the light emitted by the light-emitting elements 2 can be reduced through arrangement of the flexible light-shielding layer 8, so that the light emitted by the light-emitting elements 2 can be more sufficiently transmitted to the light-transmitting regions 31 of the flexible display layer 3 in a concentrated manner, thereby improving the light display effect of the display module. During specific implementation, the flexible light-shielding layer 8 can be made of an opaque flexible material such as silica gel, rubber and silicone rubber, all that is required is to meet the use requirements, and it is not specifically limited in this embodiment.

Reference is continuously made to FIG. 4. In some optional embodiments of the present application, a second viscous layer 82 is provided on a surface of one side of the flexible light-shielding layer 8 facing the flexible printed circuit board 1. Thus, through arrangement of the second viscous layer 82, the flexible light-shielding layer 8 can be conveniently and quickly stacked on the first surface 11 of the flexible printed circuit board 1, or the flexible light-shielding layer 8 can be conveniently and quickly stacked on the flexible light-reflecting layer 6. During specific implementation, the second viscous layer 82 can be glue in the type such as a double-faced adhesive tape and a structural adhesive, all that is required is to meet the use requirements, and it is not specifically limited in this embodiment.

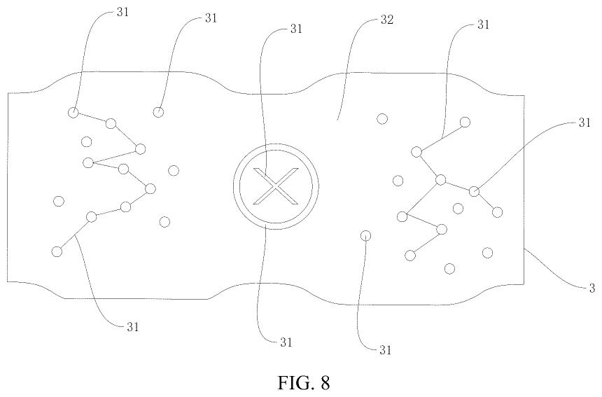

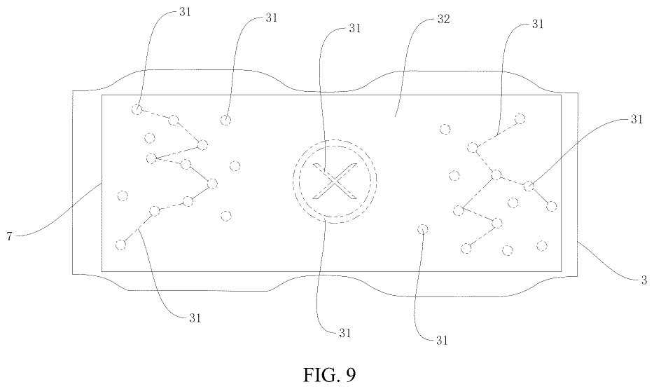

Correspondingly, reference is made to FIGS. 1-11. The present application further provides an aerosol generation apparatus. The aerosol generation apparatus includes an outer shell 9, a power supply module (not shown) mounted inside the outer shell 9, and the bendable display module according to any one of the above embodiments, where the bendable display module is fixed to an outer surface of the outer shell 9 and surrounds the outer shell 9 in a circumferential direction of the outer shell 9; and the flexible printed circuit board 1 is located between the flexible display layer 3 and the outer shell 9, and the flexible printed circuit board 1 is electrically connected to the power supply module. The power supply module can specifically include a battery and a control circuit board, where the control circuit board is respectively electrically connected to the battery and the circuit trajectory 14 of the flexible printed circuit board 1.

In this embodiment, due to the improvement of the bendable display module, the aerosol generation apparatus in this embodiment has the advantages of large display area and capability of displaying more visual information to the user. It should be noted here that during specific implementation, the display module can surround the outer shell 9 in the circumferential direction of the outer shell 9 in a half-surrounded (at this time, the display module can enclose an open ring shape such as a “U” shape) or full-surrounded (at this time, the display module can enclose a closed ring shape such as an “O” shape) manner, the specific surrounding manner of the display module can be determined according to the actual use requirements, and it is not specifically limited in this embodiment.

It should be noted here that other contents of the bendable display module and the aerosol generation apparatus disclosed in the present application can refer to the prior art and are not repeated here.

The above are only the preferred embodiments of the present application, and do not limit the scope of the patent of the present application. Any equivalent structural transformation made under the utility model concept of the present application by using the contents of the description and the accompanying drawings of the present application, or direct/indirect application in other relevant technical fields, is included in the scope of protection of the patent of the present application.

What is claimed is:

1. A bendable display module, comprising:
a flexible printed circuit board with a circuit trajectory, wherein the flexible printed circuit board has a first surface in a thickness direction thereof;
a plurality of light-emitting elements which are distributed on the first surface at intervals and are electrically connected to the circuit trajectory; and
a flexible display layer which is fixedly stacked on the first surface and covers the light-emitting elements, wherein the flexible display layer has a plurality of light-transmitting regions, each of the light-transmitting regions is provided opposite to at least one of the light-emitting elements, and a region of the flexible display layer apart from the light-transmitting regions is a light-shielding region.

2. The bendable display module according to claim 1, further comprising a current driving element and a current input interface, wherein the first surface has a first mounting region and a second mounting region which are connected to each other, the area of the first mounting region is greater than that of the second mounting region, the second mounting region is provided on an edge of the flexible printed circuit board, the plurality of light-emitting elements are fixed to the first mounting region, and the current driving element and the current input interface are mounted on the second mounting region at intervals and are electrically connected to the circuit trajectory.

3. The bendable display module according to claim 2, wherein a notch is formed in the edge of the flexible printed circuit board, the second mounting region is located inside the notch, and a region of the first surface apart from the second mounting region is the first mounting region.

4. The bendable display module according to claim 2, wherein a plurality of test points made of metal materials are further provided on the second mounting region in an exposed manner, and the plurality of test points are electrically connected to the circuit trajectory.

5. The bendable display module according to claim 2, further comprising a metal sheet, wherein the metal sheet is fixed to one side of the flexible printed circuit board facing away from the second mounting region.

6. The bendable display module according to claim 5, wherein at least one positioning hole is formed in a surface of the metal sheet.

7. The bendable display module according to claim 2, further comprising a flexible flat cable, wherein one end of the flexible flat cable is inserted into the current input interface.

8. The bendable display module according to claim 1, further comprising a first viscous layer, wherein the flexible printed circuit board further has a second surface facing away from the first surface, and the first viscous layer is provided on the second surface.

9. The bendable display module according to claim 1, further comprising a flexible light-reflecting layer, wherein the flexible light-reflecting layer covers the first surface, and the light-emitting elements are exposed out of the flexible light-reflecting layer.

10. The bendable display module according to claim 1, further comprising a flexible light-shielding layer, wherein a plurality of light-transmitting holes are formed in the flexible light-shielding layer, the flexible light-shielding layer is sandwiched between the flexible printed circuit board and the flexible display layer, and each of the light-transmitting holes is provided opposite to at least one of the light-transmitting regions.

11. The bendable display module according to claim 10, wherein the flexible light-shielding layer is made of an opaque silica gel, rubber or silicone rubber material.

12. The bendable display module according to claim 10, wherein a second viscous layer is provided on a surface of one side of the flexible light-shielding layer facing the flexible printed circuit board.

13. The bendable display module according to claim 1, wherein a third viscous layer is provided on a surface of one side of the flexible display layer facing the flexible printed circuit board.

14. The bendable display module according to claim 1, wherein the light-emitting elements are LED lamp beads.

15. The bendable display module according to claim 14, wherein the light-emitting elements are LED lamp beads with dimensions being 0.5-1.5 mm in length, 0.2-0.8 mm in width and 0.1-0.8 mm in thickness.

16. The bendable display module according to claim 15, wherein the light-emitting elements are LED lamp beads with dimensions being 1.0 mm in length, 0.5 mm in width and 0.4 mm in thickness.

17. The bendable display module according to claim 1, wherein the flexible printed circuit board comprises any one of a polyimide film and a polyester film.

18. The bendable display module according to claim 1, further comprising a flexible diffusion layer, wherein the flexible diffusion layer is attached to a surface of one side of the flexible display layer facing the flexible printed circuit board, and the flexible diffusion layer covers the light-transmitting regions.

19. The bendable display module according to claim 18, wherein a fourth viscous layer is provided on a surface of one side of the flexible diffusion layer facing away from the flexible display layer.

20. An aerosol generation apparatus, comprising an outer shell, a power supply module mounted inside the outer shell, and the bendable display module according to claim 1, wherein the bendable display module is fixed to an outer surface of the outer shell and surrounds the outer shell in a circumferential direction of the outer shell; and the flexible printed circuit board is located between the flexible display layer and the outer shell and is electrically connected to the power supply module.
